(19) United States
(12) Patent Application Publication
(10) Pub. No.: US 2005/0172178 A1
(43) Pub. Date: Aug. 4, 2005

(54) Cache-testable processor identification

(76) Inventor: Elias Gedamu, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/759,373

(22) Filed: Jan. 15, 2004

(51) Int. Cl. G11B 5/00; G06K 5/04; G11B 20/20; G11C 29/00

(52) U.S. Cl. 714/718

(57) ABSTRACT

Systems, methods, and computer programs for performing cache yield analysis of a processor design are provided. One embodiment is a system for testing cache performance of a processor design. Briefly described, one such system comprises: means for searching a file that contains test results for a lot of wafers; and means for identifying all processors on wafers in the lot in which a cache array has passed a cache test.

### BACKGROUND

Currently, a number of systems exist for testing various types of semiconductor-based devices. In general, such systems interface with the device-under-test (DUT) and perform various analyses to test the operation, functionality, etc. of the DUT. Typically, the results of these tests are logged to a results file for subsequent analysis to assess the processor design and/or the yield of the fabrication process.

Existing systems for analyzing the results file, however, are limited because of the large size of the file. The results file is typically very large because the test system performs a number of tests for each processor on each wafer in the lot.

### SUMMARY

Systems, methods, and computer programs for performing cache yield analysis of a processor design are provided. One embodiment is a method for testing cache performance of a processor design which comprises searching a file that contains test results for a lot of wafers; and identifying at least one processor on one of the wafers in the lot in which a cache array has passed a cache test.

Another embodiment is a system for testing cache performance of a processor design which comprises: a parser module for searching a file that contains test results for a lot of wafers; and a cache-testable processor identification module for identifying processors on wafers in the lot in which a cache array has passed a cache test.

A further embodiment is a computer program embodied in a computer-readable medium, such computer program comprising logic configured to search a file that contains test results for a lot of wafers; and logic configured to identify at least one processor on one of the wafers in the lot in which a cache array has passed a cache test.

### BRIEF DESCRIPTION OF THE DRAWINGS

Many aspects of the invention can be better understood with reference to the following drawings. The components in the drawings are not necessarily to scale, emphasis instead being placed upon clearly illustrating principles in accordance with exemplary embodiments of the present invention. Moreover, in the drawings, like reference numerals designate corresponding parts throughout the several views.

FIG. 1 is a block diagram of a testing environment for testing processors, which includes a cache-testable processor identification system.

FIG. 2 is a perspective view illustrating a lot of wafers that may be tested in the testing environment of FIG. 1.

FIG. 3 is a more detailed block diagram of a portion of the testing environment of FIG. 1 illustrating the general components of processors on the wafers of FIG. 2.

FIG. 4 is a simplified diagram illustrating an exemplary representation of the cache array in the processor of FIG. 3.

FIG. 5 is a flowchart illustrating the architecture, operation, and/or functionality of an embodiment of the cache-testable processor identification system of FIGS. 1 and 3.

FIG. 6 is a block diagram of another embodiment of the cache-testable processor identification system of FIGS. 1 and 3.

### DETAILED DESCRIPTION

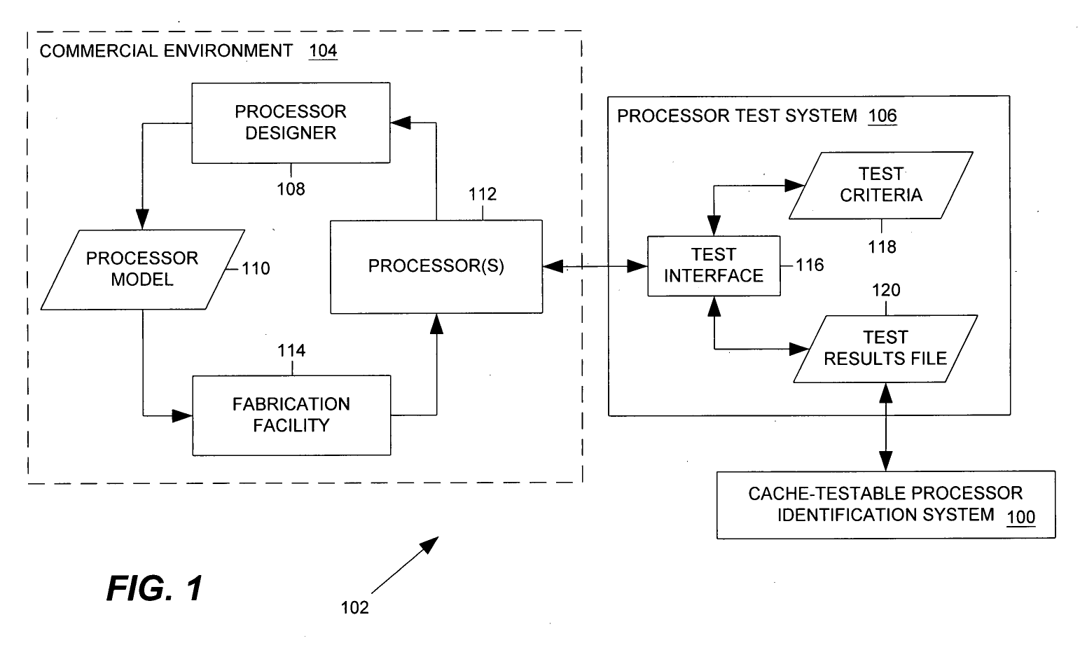

This disclosure relates to various embodiments of systems, methods, and computer programs for testing cache performance of a processor design. Several embodiments will be described below with reference to FIGS. 1-6. As an introductory matter, however, the basic architecture, operation, and/or functionality of an exemplary embodiment of a cache-testable processor identification system will be briefly described.

In one exemplary embodiment, a cache-testable processor identification system is configured to interface with a file that contains results of various tests performed on processor(s) in a collection of wafers (i.e., lot). The cache-testable processor identification system is configured-to search the file and identify processors on wafers in the lot for which a cache array has passed a cache test. For example, in one embodiment, the cache-testable processor identification system interprets the data in the file and determines processors in which the built-in-self-test (BIST) engine was able to execute the cache test. It should be appreciated that this information regarding which processors passed the cache test (i.e., the processor was cache-testable) may be useful to processor designers and/or manufacturers for performing additional analysis.

FIG. 1 illustrates an embodiment of a processor design/manufacture/test environment 102 in which various embodiments of a cache-testable processor identification system 100 may be implemented. As illustrated in the embodiment of FIG. 1, environment 102 comprises commercial environment 104, processor test system 106, and cache-testable processor identification system 100. In commercial environment 104, a processor designer 108 designs a processor to be manufactured. As further illustrated in FIG. 1, the architecture, functionality, layout (or floorplan), etc. may be embodied in a processor model 110 that may be provided to a fabrication facility 114 for manufacture. Fabrication facility 114 manufacturers processors 112 according to processor model 110. It should be appreciated that any type of processor may be designed and manufactured.

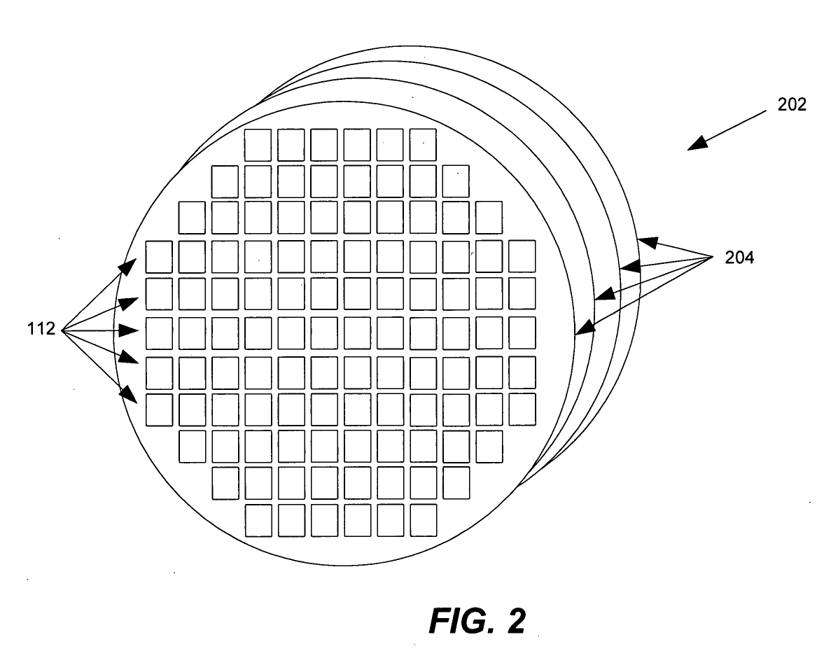

Referring to FIG. 2, it should be further appreciated that fabrication facility 114 typically manufactures a lot 202 of wafers 204. As known in the art, a wafer 204 comprises a number of processors 112. Referring again to FIG. 1, processor test system 106 may be used to test any aspect of processors 112 (e.g., operation, functionality, etc.) in lot 202, or various components of processors 112. In this regard, processor test system 106 comprises a test interface 116, test criteria 118, and a test results file 120.

Test criteria 118 may comprise a data file or logic that defines and/or controls the test(s) to be performed on processors 112. One of ordinary skill in the art will appreciate that any of a variety of types of tests may be performed on processors 112 and, therefore, test criteria 118 may be configured accordingly. Various embodiments of test criteria 118 may be configured to test the cache components (e.g., instruction cache, data cache, etc.) of processors 112.

As illustrated in FIG. 1, test interface 116 provides the interface between test criteria 118 and processors 112 to be tested. Test interface 116 may be configured to provide the physical, functional, or other interface means between these components.

As known in the art, during operation of processor test system 106, the results of the tests performed on each processor 112, wafer 204, and/or the corresponding aspects of processors 112 or wafer 204 may be logged to test results file 120. Typically, due to the large number of tests being performed and the large number of processors 112, test results file 120 is relatively large. It should be appreciated that test results file 120 may be configured in a variety of ways. For example, test results file 120 may be represented in hexadecimal, binary, or other suitable data formats.

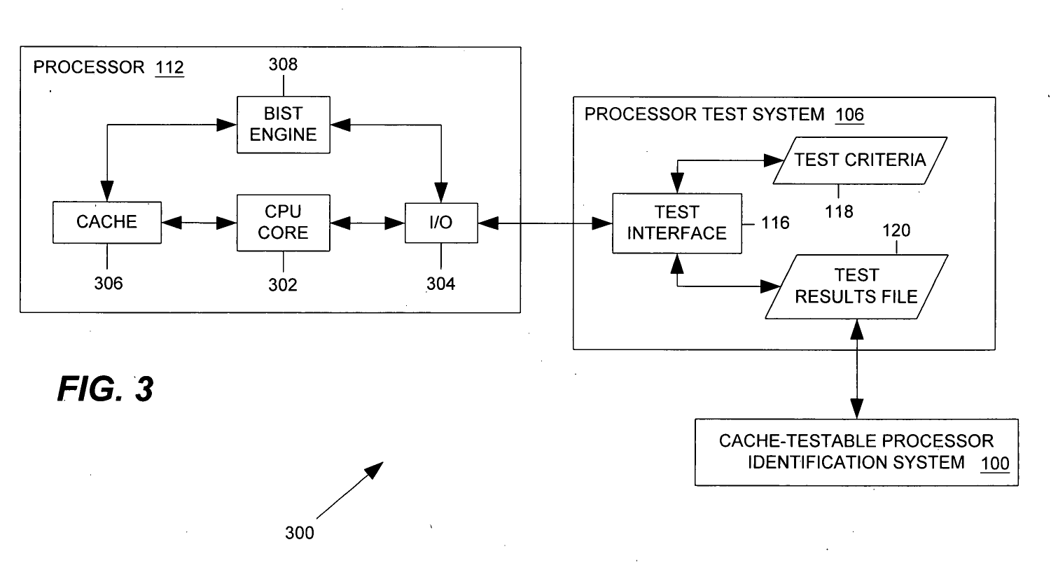

FIG. 3 illustrates an example of a processor architecture that may be employed in processors 112. In this embodiment, processor 112 comprises I/O 304, a CPU core 302, a built-in-self-test (BIST) engine 308, and cache 306. I/O 304 provides an interface mechanism by which processor test system 106 may test cache 306 via BIST engine 308. As briefly mentioned above, test processor system 106 may test the cache components (e.g., instruction cache, data cache, etc.) of processors 112. In this regard, processor test system 106 may instruct (BIST) engine 308 to execute a test of cache 306.

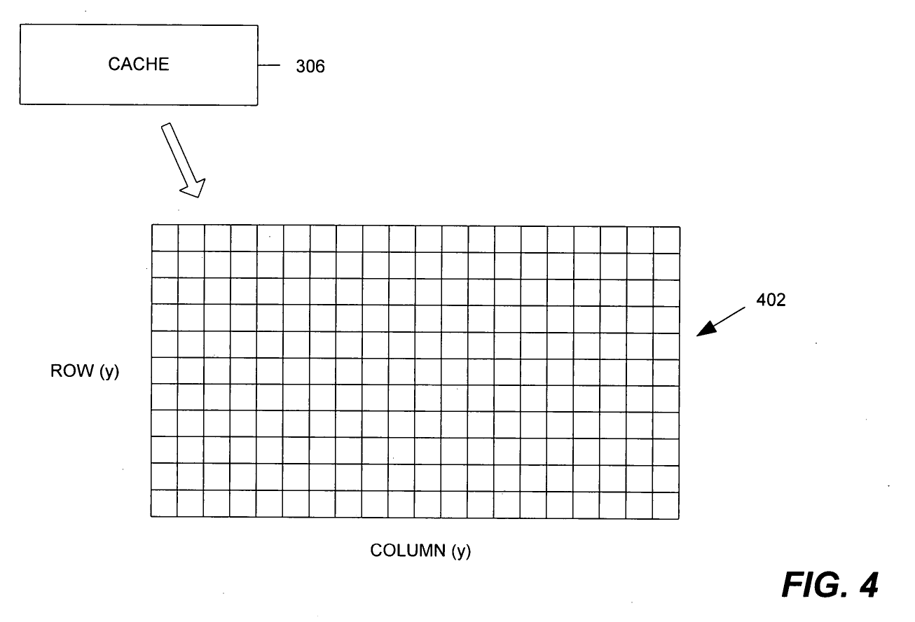

Referring to FIG. 4, cache 306 may comprise a cache array 402 comprising various rows and columns. It should be appreciated that cache array 402 may be configured in a variety of ways and need not be configured in a symmetrical array.

Rather, cache array 402 defines a grid that may be identified by X-Y coordinates corresponding to a bit at a particular location in cache array 402. As known in the art, a cache test may be performed to test various aspects of the cache array 402. In this regard, it should be appreciated that test results file 120 contains data corresponding to the particular tests to be performed.

As briefly described above, cache-testable processor identification system 100 may be configured to interface with test results file 120. Cache-testable processor identification system 100 may be configured to search test results file 120 and identify cache-testable processors 112 on wafers 204 in lot 202. In one embodiment, cache-testable processor identification system 100 identifies processors 112 for which a cache array 402 has passed a cache test. In other embodiments, cache-testable processor identification system 100 interprets the data in test results file 120 and determines processors 112 in which built-in-self-test (BIST) engine 308 was able to execute the cache test.

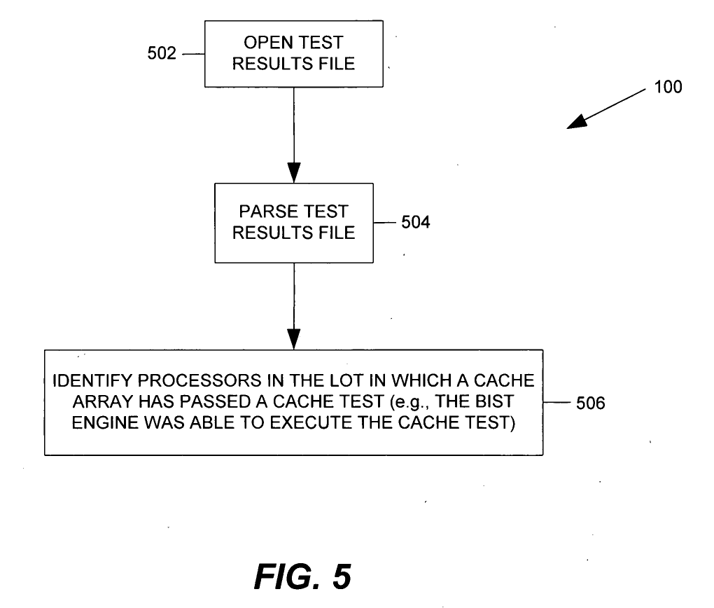

FIG. 5 illustrates the architecture, operation, and/or functionality of an embodiment of cache-testable processor identification system 100. At block 502, cache-testable processor identification system 100 opens test results file 120. At block 504, cache-testable processor identification system 100 parses test results file 120. At block 506, cache-testable processor identification system 100 identifies which processors 112 in lot 202 were cache-testable in the manner described above.

One of ordinary skill in the art will appreciate that this type of information may be useful to designers and/or manufacturers for performing subsequent analysis of test results file 120. In this manner, cache-testable processor identification system 100 may perform a high-level search to identify cache-testable processors 112. After the cache-testable processors 112 are identified a more granular cache analysis may be performed.

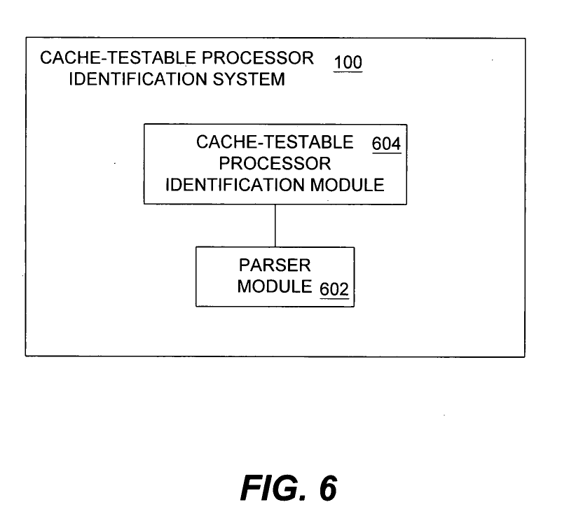

FIG. 6 illustrates another embodiment of cache-testable processor identification system 100. In the embodiment illustrated in FIG. 6, cache-testable processor identification system 100 comprises a parser module 602 and a cache-testable processor identification module 604. Parser module 602 may be configured to search test results file 120. In the manner described above, module 604 may interpret the data in test results file 120 and identify processors 112 that were cache-testable. Depending on the data format of test results file 120, parser module 602 and module 604 may employ a number of types of mechanisms for decompressing, decoding, etc. the relevant data.

One of ordinary skill in the art will appreciate that cache-testable processor identification system 100 may be implemented in software, hardware, firmware, or a combination thereof. Accordingly, in one embodiment, cache-testable processor identification system 100 is implemented in software or firmware that is stored in a memory and that is executed by a suitable instruction execution system. In software embodiments, cache-testable processor identification system 100 may be written any computer language. In one exemplary embodiment, cache-testable processor identification system 100 comprises a PERL script.

In hardware embodiments, cache-testable processor identification system 100 may be implemented with any or a combination of the following technologies, which are all well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

It should be appreciated that the process descriptions or blocks related to FIGS. 5 and 6 represent modules, segments, or portions of code which include one or more executable instructions for implementing specific logical functions or steps in the process. It should be further appreciated that any logical functions may be executed out of order from that shown or discussed, including substantially concurrently or in reverse order, depending on the functionality involved, as would be understood by those reasonably skilled in the art.

Furthermore, cache-testable processor identification system 100 may be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer-readable medium can be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory.

1. A method for testing cache performance of a processor design, the method comprising:
searching a file that contains test results for a lot of wafers; and
identifying at least one processor on one of the wafers in the lot in which a cache array has passed a cache test.

2. The method of claim 1, wherein the identifying the at least one processor comprises identifying that a built-in-self-test (BIST) engine in the at least one processor was able to execute the cache test.

3. The method of claim 1, further comprising identifying all of the processors in the lot in which a cache array has passed the cache test.

4. The method of claim 3, wherein the identifying all of the processors comprises identifying that a built-in-self-test (BIST) engine in each of the processors was able to execute the cache test.

5. The method of claim 1, wherein the searching the file comprises parsing the file.

6. The method of claim 1, wherein the searching the file comprises opening the file and parsing the file.

7. The method of claim 1, wherein the searching the file comprises decompressing the file.

8. A system for testing cache performance of a processor design, the system comprising:
a parser module for searching a file that contains test results for a lot of wafers; and
a cache-testable processor identification module for identifying processors on wafers in the lot in which a cache array has passed a cache test.

9. The system of claim 8, wherein the parser module is configured to open the file that contains the test results.

10. The system of claim 8, wherein the parser module and the cache-testable processor identification module comprise software that is executed by a processor.

11. The system of claim 8, wherein the cache-testable processor identification module is configured to identify the processors for which a built-in-self-test (BIST) engine was able to execute the cache test.

12. The system of claim 8, wherein the parser module and the cache-testable processor identification module comprise a PERL script.

13. A computer program embodied in a computer-readable medium, the program comprising:
logic configured to search a file that contains test results for a lot of wafers; and
logic configured to identify at least one processor on one of the wafers in the lot in which a cache array has passed a cache test.

14. The computer program of claim 13, wherein the logic configured to identify the at least one processor comprises logic configured to identify that a built-in-self-test (BIST) engine in the at least one processor was able to execute the cache test.

15. The computer program of claim 13, wherein the logic configured to search the file comprises logic configured to parse the file.

16. The computer program of claim 13, wherein the logic configured to search the file comprises logic configured to decompress the file.

17. A system for testing cache performance of a processor design, the system comprising:
means for searching a file that contains test results for a lot of wafers; and
means for identifying all processors on wafers in the lot in which a cache array has passed a cache test.
